(19) United States
(12) Patent Application Publication
(10) Pub. No.: US 2009/0022574 A1
(43) Pub. Date: Jan. 22, 2009

(54) WORKPIECE LOADING SYSTEM

(76) Inventors: Steve L. Eudy, Kalispell, MT (US); Randy A. Harris, Kalispell, MT (US); Paul Z. Wirth, Whitefish, MT (US)

Correspondence Address: PERKINS COIE LLP/SEMITOOL, PO BOX 1208, SEATTLE, WA, 98111-1208, US

(21) Appl. No.: 11/778,588

(22) Filed: Jul. 16, 2007

(51) Int. Cl. H01L 21/677; B66F 11/00; G06F 19/00

(52) U.S. Cl. 414/589; 414/659; 414/800; 700/245; 901/14

(57) ABSTRACT

A wafer loading system accommodates sufficient wafer carriers to substantially maximize the processing speed capability of wafer processing systems. Wafer carriers are placed into and removed from the loading system by one or two overhead carrier loading elements, such as overhead track systems. Carriers may be loaded or removed while other carriers are in work. One or more transfer robots may move wafers from the carriers to buffers. Methods of operating the loading system allow delivery and removal of wafers to and from the processing systems to meet or exceed the processing speeds of the processing systems.

### BACKGROUND OF THE INVENTION

The semiconductor manufacturing industry has achieved remarkable success in reducing manufacturing costs. As a result, the cost of most electronic products continues to drop, even as these products provide ever greater capabilities and value. In the past, some of the lower manufacturing costs have been achieved by running large lots of wafers in large batch processing machines. However, the semiconductor manufacturing industry is now tending to move away from batch processing and toward single wafer processing. Consequently, techniques for speeding up single wafer processing are needed.

A significant productivity challenge in semiconductor device manufacturing is process waiting time. For every minute that a micro-electronic substrate or wafer undergoes processing, the wafer may be completely idle for 20-30 minutes or more, while waiting for the next process to begin. Cycle-time is the total time required for a wafer to move through the entire manufacturing process. Reducing cycle time can allow device manufacturers flexibility to adapt product type to rapidly changing market demands. Wafer lot size is the size of the lot or batch of wafers moving as a group through the manufacturing processes. Currently, a common wafer lot size is 25, i.e., the wafers move through the manufacturing facility or fab in groups of 25 (typically within a carrier capable of holding up to 25 wafers). At each tool or station, the carrier must wait until the entire lot of e.g., 25 wafers is processed. If, on the other hand, the lot size is reduced to say 5 wafers, waiting time and cycle time can be significantly reduced. The overall inventory of wafers moving through the fab can also be reduced. Both of these factors reduce manufacturing costs.

Although reducing wafer lot sizes from 25 wafers per carrier to say five wafers per carrier may conceptually be a relatively simple transition, in the real world it creates difficult engineering challenges. Going from 25 to 5 wafers per carrier requires moving the same number of wafers through the fab, but using five times more individual carrier movements. Apart from simply moving carriers faster, other factors, such as carrier storage and waiting locations, carrier access, carrier movement patterns, carrier loading system speed, etc. can affect ultimate manufacturing costs.

In addition, even with current technology, when specific process times are relatively short, say for example, less than 2 or 3 minutes per wafer, the processing systems can often process wafers more quickly than the wafer transport systems in the fab can deliver wafers to the processing systems, and/or more quickly than wafer loading systems can load or unload wafers. Consequently, the processing systems are often processing wafers at rates below their maximum processing capability. As a result, manufacturers are not able to achieve all of cost savings that such processing systems can offer.

Accordingly, improved systems and methods are needed.

### SUMMARY OF THE INVENTION

A wafer loading system for loading and unloading wafers into and from various types of wafer processing systems accommodates sufficient wafer carriers to substantially maximize the processing speed capability of the processing system. The loading system also allows for operation with carriers having smaller numbers of wafers, to reduce waiting time during manufacturing. Wafer carriers are placed into and removed from the loading system by one or two overhead carrier loading elements, such as overhead tracks. Carriers may be loaded or removed while other carriers are in work. Larger numbers of carriers may also be simultaneously accessed. The wafer loading system may be used with existing processing systems, to increase manufacturing efficiency.

This summary is included to provide a brief overview of the invention. However, the features and advantages described here are not requirements or limitations on the invention, and should not be taken as such. Rather, the limitations of the invention are set forth in the claims.

### BRIEF DESCRIPTION OF THE DRAWINGS

In the drawings, wherein the same reference number indicates the same element in each of the views:

FIG. 1 is a front perspective view of a novel loading system.

FIG. 2 is a rear perspective view of the loading system shown in FIG. 1.

FIG. 3 is a plan view of the loading system used with a processing system having two spaced apart arrays of process chambers.

FIG. 4 is a plan view of the loading system used with a processing system having process chambers in a generally circular or other geometric pattern.

FIG. 5 is a plan view of the loading system used with a cluster tool processing system.

FIG. 6 is a section view of the loading system set up to operate in a shuttle pattern mode.

FIG. 7 is a block diagram indicating operation of the system shown in FIG. 6.

FIG. 8 is a section view of the loading system set up to run in a swap pattern mode.

FIG. 9 is a block diagram indicating operation of the system shown in FIG. 8.

FIG. 10 is a section view of the set up to run in an access pattern mode.

FIG. 11 is a block diagram indicating operation of the system shown in FIG. 10.

FIG. 12 is a section view of the loading system set up to run in a stacked pattern mode.

FIG. 13 is a block diagram indicating operation of the system shown in FIG. 12.

### DETAILED DESCRIPTION OF THE DRAWINGS

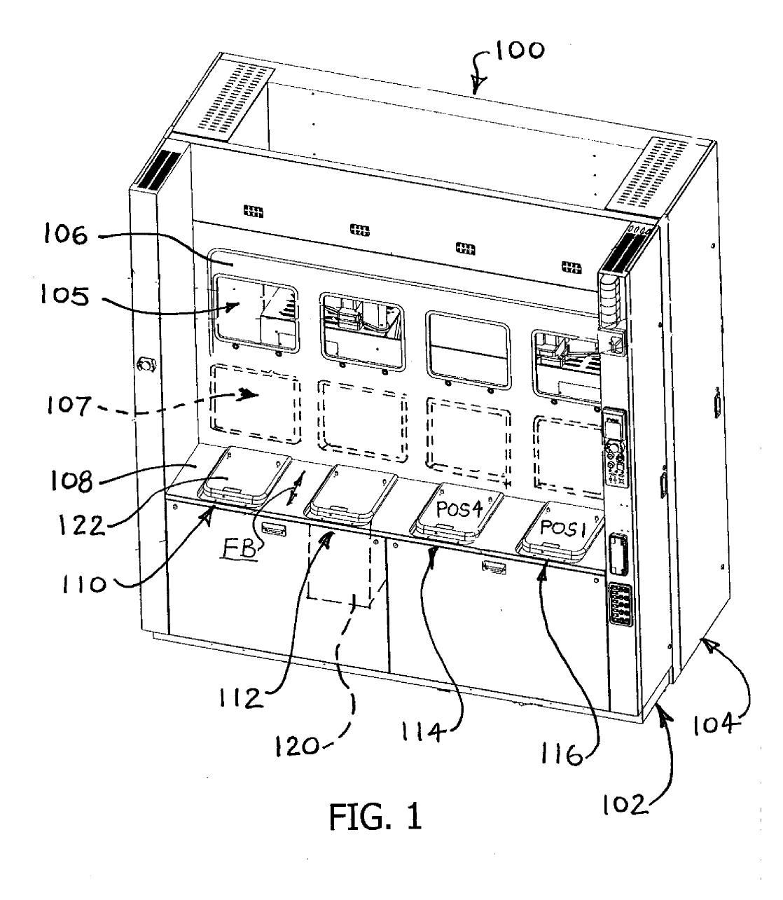

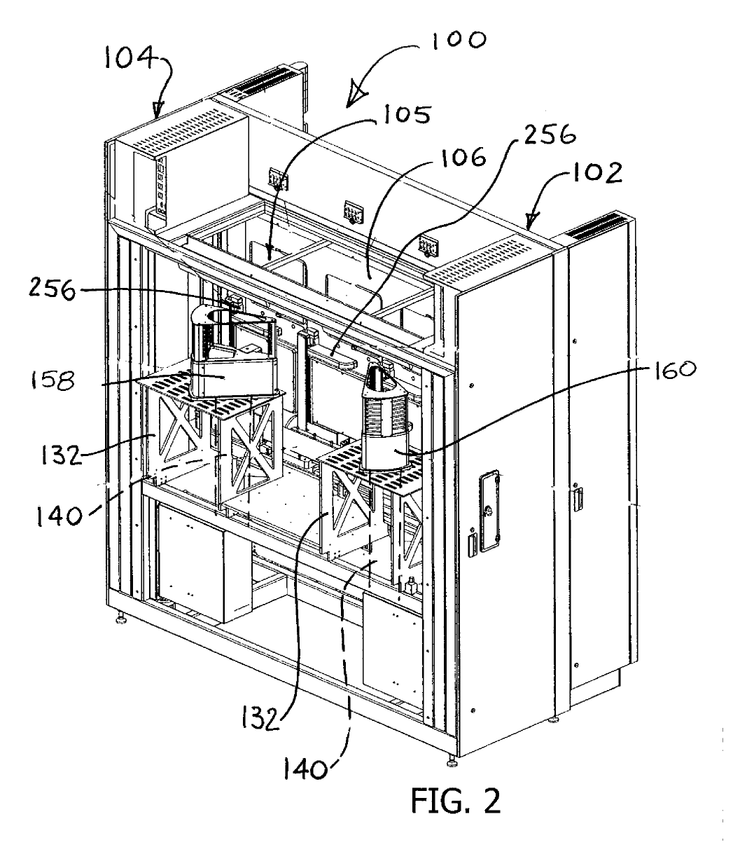

As shown in FIGS. 1 and 2, a new loading system 100 is provided for use with wafer processing systems. The loading system 100 has a container (FOUP) module 102 and a wafer transfer module 104. The FOUP module 102 has FOUP plates 122 generally at the vertical level of a loading deck 108. The plates 122 have fittings for receiving and holding a FOUP container 101 or a similar container. Each of the four plates 122 is supported on a shuttle actuator 120 adapted to move the plate 122 linearly in the direction of arrow FB. The plates 122 are typically evenly spaced apart and define FOUP loading columns or aisles shown as 110, 112, 114 and 116.

Referring still to FIGS. 1 and 2, the FOUP module 102 includes a docking wall 106 with a docking opening 105 in the wall 106 at each of the FOUP columns 110, 112, 114 and 116. Additional docking openings 107 may also be provided in the wall 106, typically laterally aligned with, and vertically below, the docking openings 105. FIG. 2 shows a FOUP door remover 256 associated with each docking opening 105. Buffers 158 and 160 are supported on buffer platforms 132, so that the buffers are at a convenient vertical position.

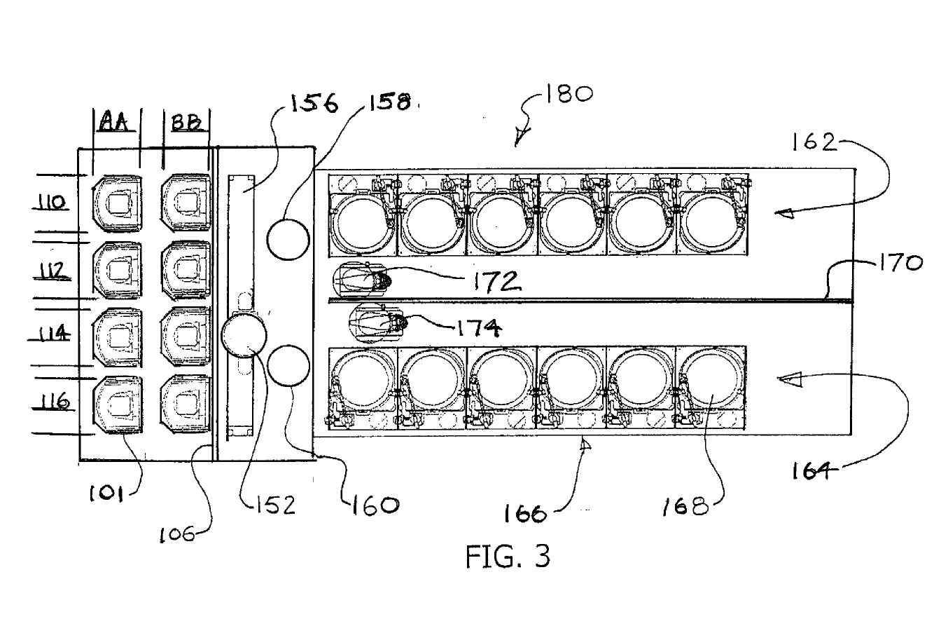

Turning to FIG. 3, the loading system 100 is shown attached to a process module 166 to form a processing system 180. A transfer robot 152 moves wafers between FOUPs at the docking wall 106 and the buffers 158 and 160. FIG. 3 shows a single transfer robot 152 that moves laterally on a track 156. The transfer robot 152 may alternatively be mounted on at a centrally located fixed position with movements to each FOUP columns 110, 112, 114 and 116 achieved via articulation of the robot arm. The end effector of the robot 152 may hold 1, 2, 3, 4, 5 or more wafers.

The loading system may alternatively use two transfer robots. In this design, a first transfer robot typically moves wafers between docked FOUPs in columns 110 and 112 and the first buffer 158. A second transfer robot 154 similarly moves wafers between docked FOUPs in columns 114 and 116 and the second buffer 160. In this way, each transfer robot operates within in own dedicated space, with few, if any, interfering or overlapping transfer robot movements occurring. Conflict or collision avoidance control software is accordingly not needed, allowing the transfer robots to move more quickly.

The process module 166 shown in FIG. 3 has a first section 162, a second section 164, and an optional divider wall 170 separating the first and second sections. The divider wall 170 may extend the full length and height of the process module 166, to substantially isolate the first section 162 from the second section 164. Each of the sections 162 and 164, as shown in FIG. 3, includes a linear array of wafer processors or process chambers 168. A first process robot 172 in the first section 162, and a second process robot 174 in the second section 164 are movable along rails, to allow each process robot to access each of the processors in its section. In operation, the first process robot 172 picks up one or more wafers from the first buffer 158 and delivers them to the processors 168 in the first section 162. Within a processor 168, the wafer is typically rotated, while one or more process liquids or gases are applied onto the wafer, in a spin/spray method. The wafer may then be dried within the processor. The process module 166 may be designed and/or operated as described, for example in U.S. patent application Ser. No. 11/620,508, incorporated herein by reference. The processing system 180 may be designed and operated as described in U.S. Pat. Nos. 6,900,132; 6,350,319; 6,264,752, each incorporated herein by reference. U.S. patent application Ser. No. 11/______, 54008.8248.US00/P07-0019, filed on Jul. 16, 2007, is also incorporated herein by reference.

After processing, the wafers are then returned to the first buffer 158 by the first process robot 172. The transfer robot 152 then moves the now processed wafers from the first buffer 158 back into a docked FOUP. Operation of the second side 164 is the same as, but independent of, the first section 162. As each section 162 and 164 of the process module 166 operates independently, the speed of operation of either section is independent of the other. In addition, either section may be idled, for example, for service or calibration, while the other section continues with normal processing operations. The processors 168 on each section 162 and 164 may share common process fluid supplies, electrical power supplies, and drain/exhaust connections (all typically provided underneath the deck holding the processors 168), or they may each have independent supplies or connections.

In the process module 166, although two process robots 172 and 174 are used, again, each of the process robots operates exclusively within its own space. Specifically, the first process robot 172 typically moves only between the first buffer 158 and the processors 168 on the first side 162, while the second process robot 174 correspondingly typically moves only between the second buffer 160 and the processors 168 on the second side 164. Conflict avoidance control software is therefore also not needed for controlling the process robots 172 and 174. This allows the process robots to operate more quickly. At the same time, the potential for wafer or robot damage caused by collisions resulting from the robots accessing the same spaces is greatly reduced. The process module 166 may alternatively be provided with a single process robot that accesses all processors in the module 166. In this design, no dividing wall is used.

The buffers provide temporary holding positions for the wafers. The generally wedge-shaped buffers allow the robots to pick up and place wafers in the buffers, relatively quickly and with relatively simple movements. Of course, other types of buffers having different forms and locations may be used. Indexing buffers having vertical movement may also be used. By moving the buffers (or rather the buffer shelves providing the wafer holding positions) vertically, buffer capacity may increase within a compact space. The amount of vertical robot movement may also be reduced, allowing the robots to pick and place wafers more quickly. Vertically indexing buffers may be implemented by supporting the buffers on actuators 140 shown in dotted lines in FIG. 2, instead of the platforms 132. For some applications, the buffers may be set up to be moved horizontally by the actuators, instead of, or in addition to, any vertical movement.

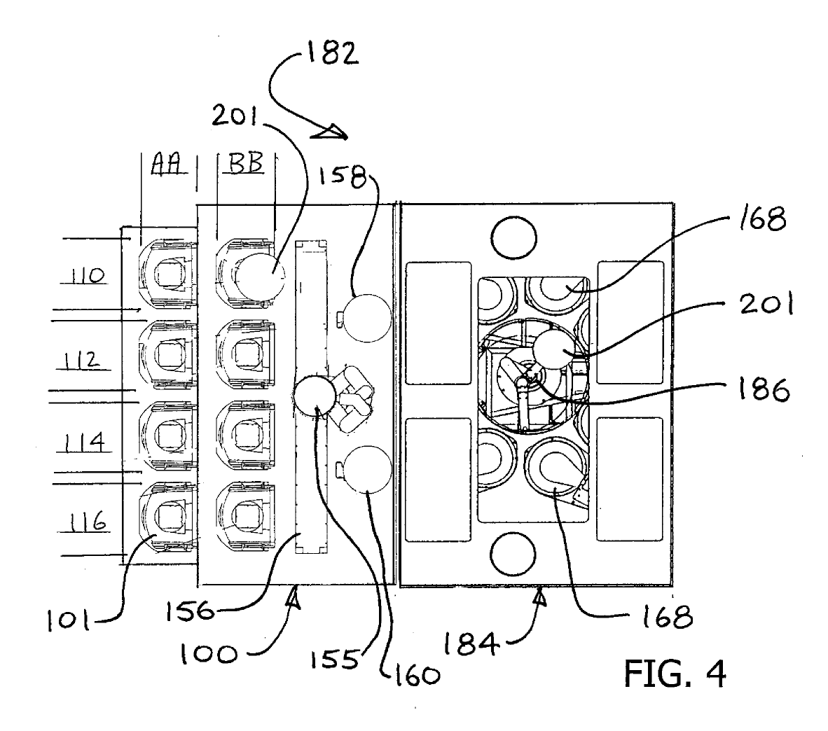

FIG. 4 shows the loading system 100 connected and operating with an alternative process module 184 to form a processing system 182. The process module 184 has processors 168 arranged around a centrally located robot 186. Wafers 201 are moved through the loading system 100 to the buffers 158 and 160, as described above. The fixed process robot 186 then moves wafers between the buffers and the processors 168 in the process module 184.

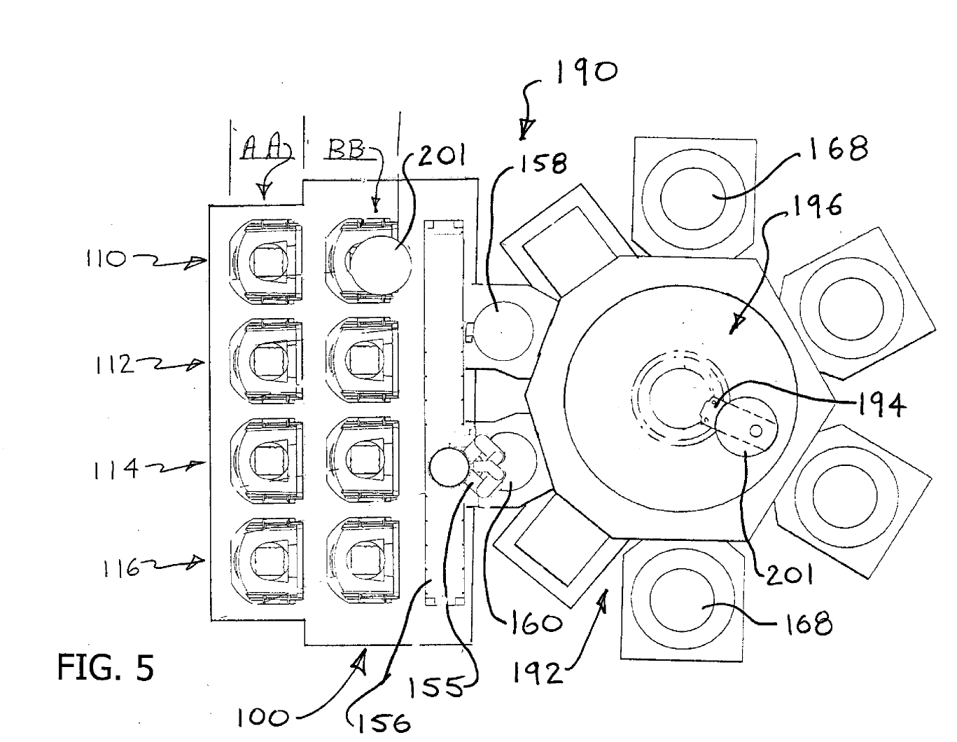

FIG. 5 shows another similar arrangement with the loading system 100 connected to and operating with a cluster process module 192, to form a processing system 190. The cluster process module 192 has multiple processors 168 arranged around a cluster tool robot 194. The processors 168 may optionally be closed off from the central area 196 of the cluster process module 192 during certain processing operations. Wafers 201 are moved through the loading system 100 to the buffers 158 and 160, as described above. One or more buffers may alternatively be provided as load locks where the central area 196 and the process areas 168 may be under vacuum. The cluster tool robot 194 then moves wafers between the buffers and the processors 168 in the cluster process module 192. In each of the process modules described, the processors 168 may be set up to perform various wafer processing steps including cleaning, rinsing and/or drying, electroplating, annealing, etc.

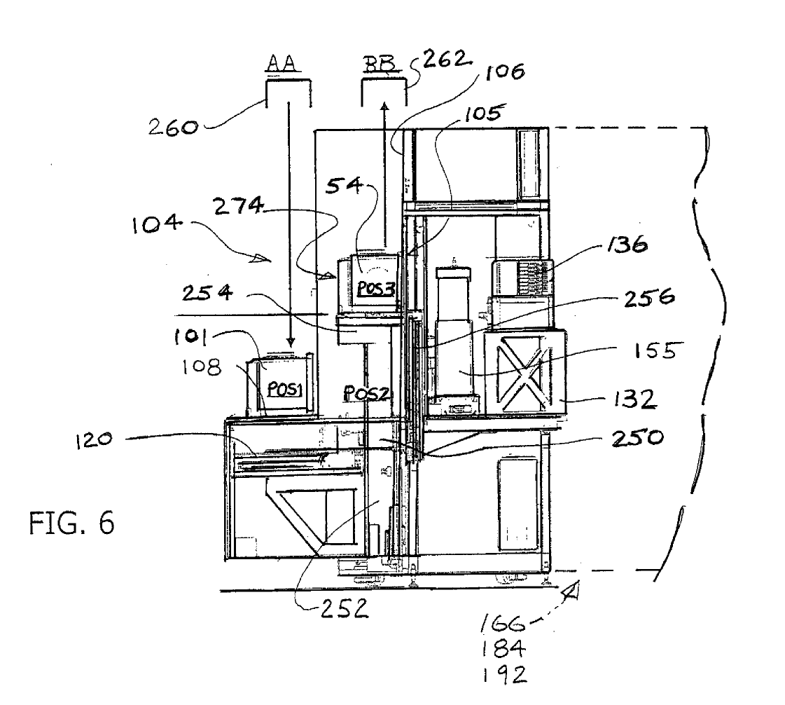

FIGS. 6-13 show and describe methods for operating the loading system 100. These methods may be used with any of the systems 180, 182 or 190. In addition, the loading system 100 and its methods of operation may also be used with other types of wafer processing or handling systems.

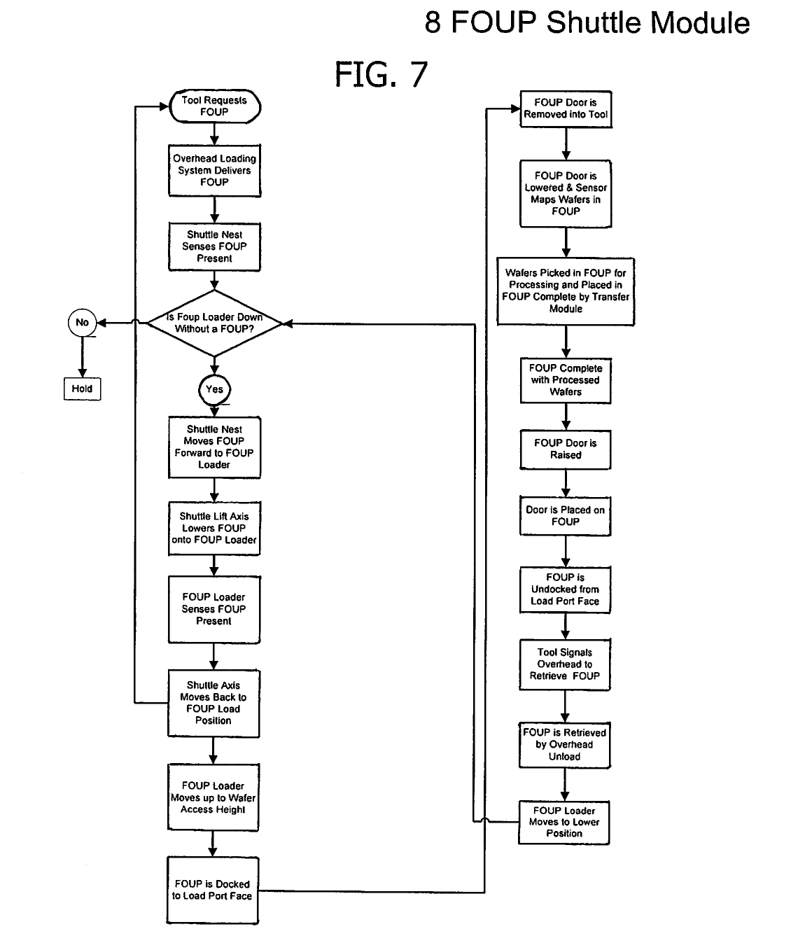

FIGS. 6 and 7 show and describe operation of the loading system 100 in an eight FOUP shuttle pattern. The FOUPs 54 are delivered to and removed from the loading system 100 from first and second overhead loading/unloading tracks 260 and 262. The overhead loading tracks 260 and 262 move FOUPs from other locations in the manufacturing facility or fab, to the processing system 180, 182 or 190, generally via computer controlled automation, as is well known in the semiconductor manufacturing field. Cars move along the tracks within the fab. FOUP holders are suspended on cables from the cars and are adapted to engage onto a fitting on top of the FOUP, to lift and lower FOUPs into selected positions, in a crane-like manner. Discussions here to operations of a loading track refer to these components or sub-systems that pick and place FOUPs, as is well known in the semiconductor manufacturing industry. The first and second tracks 260 and 262 are aligned over rows AA and BB of the loading system and are parallel to each other at this section.

Referring still to FIGS. 6 and 7, in operation, a FOUP 101 is delivered from the first overhead loading track 260 down onto a loader plate 122 in one or more of, and typically in all of, the FOUP columns 110, 112, 114 and 116, in the outer or AA row shown in FIGS. 3, 4 and 5. FIG. 6 shows a FOUP delivered to a first position labeled POS1 in row AA. The loading system then detects whether a FOUP is present and properly positioned on the plate 122, and whether a FOUP loader 250 associated with that plate is in the down position. Once these conditions are detected, the shuttle actuator 120 moves the plate and FOUP forward towards the docking wall 106, to a second position labeled POS2. The shuttle actuator 120 then lowers the FOUP onto an associated FOUP loader 250. After the FOUP loader 250 detects a FOUP present, the shuttle actuator 120 reverses direction and moves down slightly, and then rearward from row BB back to its original POS1 position at row AA. The lift actuator 252 then lifts up the FOUP loader 250 carrying a FOUP to a wafer access level 274 at position POS3, vertically aligned with a docking opening 105. For purpose of illustration, FOUPs are shown in POS1 and POS3 in FIG. 6, while POS2 is empty. POS1 is in row AA (in any column) while POS2 and POS3 are in row BB.

A docking actuator 254 then moves the FOUP incrementally further forward into a docked position at the docking opening 105 in the docking wall 106. A FOUP door remover 256 then removes the FOUP door from the FOUP and lowers it out of the way. These FOUP movements and events are typically carried out in each of the four FOUP columns 110, 112, 114, 116, simultaneously, or in as taggered manner.

A transfer robot (of any type used in the loading system) then moves wafers from the docked FOUP to a buffer. Wafers in the buffer are then moved into processors 168, are processed, and then returned to a buffer by a process robot (of any type used in the process module), as described above. The transfer robot then returns the processed wafers from the buffer to a FOUP. The FOUP door remover 256 replaces the door onto the FOUP. The docking actuator 254 then undocks the FOUP, by moving it away from the docking wall 106. The processing system controller then signals the second overhead FOUP transport track 262 to pick up the FOUP now holding processed wafers. The second overhead FOUP track 262 then engages and lifts the FOUP up off of the FOUP loader 252, at POS3, and carries it to the next station in the fab.

The lift actuator 252 then moves the loader 250 back down to POS2 at the height of the load deck 108, in preparation for receiving another FOUP. In general, the sequence described above is performed in the same way at each of the four FOUP columns 110, 112, 114 and 116, although the movements described are not necessarily performed simultaneously at each FOUP position. Rather, the shuttle actuator, FOUP loader, lift actuator, and door remover at each of the four FOUP positions may be controlled by the controller 62 for movement entirely independent of movement of these elements at any other FOUP position. Alternatively, these elements at each of the four FOUP columns which facilitate FOUP movement at each column may be controlled in ways that are fully or partially dependent on other factors, such as movement in other FOUP positions. For example, the controller 62 may be programmed so that all four FOUPS are moved in the same way, at the same time. Staggered FOUP movements may also be used. In addition, the FOUP movement pattern can be reversed, with FOUPs delivered to row BB by track 262, and removed from row AA by track 260.

The small movements performed in handing off the FOUP from the shuttle actuator to the FOUP loader, and in docking/undocking the FOUP, are not shown. For purpose of description, POS 2 includes the FOUPs horizontal position, regardless of whether the FOUP is supported by the shuttle actuator or the FOUP loader. Similarly, POS3 includes the FOUPs horizontal position regardless of whether the FOUP is docked or undocked. The vertical and horizontal movements between POS1, POS2 and POS3 (and indeed between all positions described) may be varied, and need not be straight line movements. Curving movements, and even diagonal movements may be used, although pure vertical and horizontal linear movements are generally simpler to implement.

Referring to FIGS. 3 and 6, the description of the FOUP positions POS1, POS2 and POS3 above applies at each of the FOUP columns or aisles 110, 112, 114 and 116. For purpose of description then, POS1, POS2 and POS3 may be considered as being in e.g., FOUP column 110. The equivalent positions in column 112, relative to the design in FIG. 6, would then be positions 4, 5 and 6, etc. For example, POS4 is shown adjacent to POS1 in FIG. 1.

For process modules having larger numbers of processors, or with process modules running very short processes, additional FOUP columns may be added, with the loading system 100 then having 5, 6, 7 8 or more FOUP columns. In addition, although four FOUP columns are described, the loading system may also be configured with as few as 2 or 3 columns.

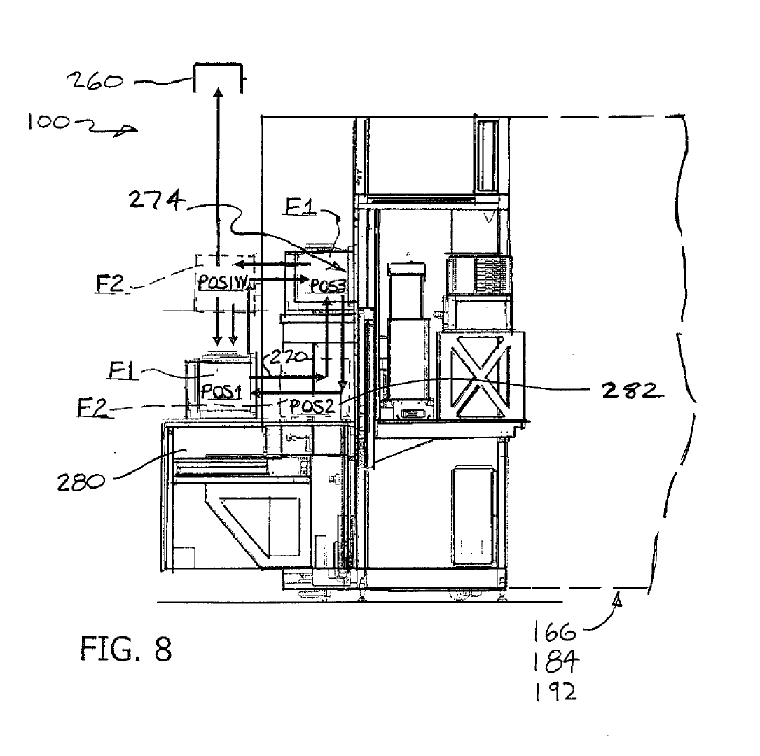

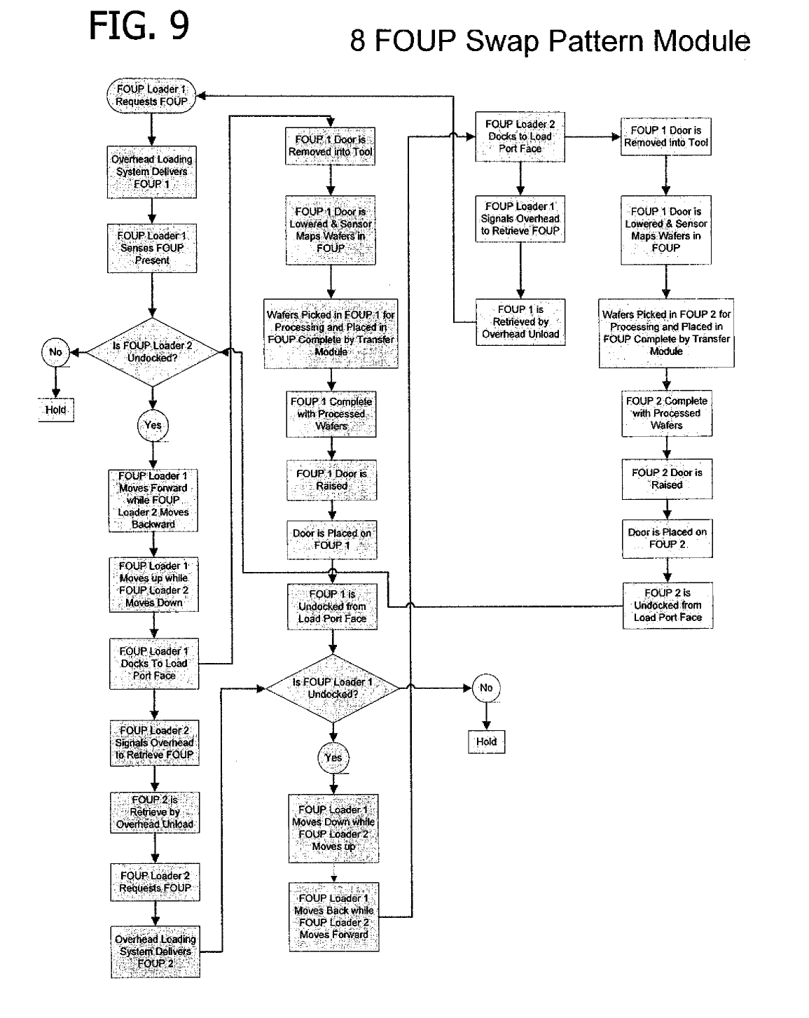

FIGS. 8 and 9 show operation of a loading system using an eight FOUP swap pattern. This design uses a first FOUP loader 280, a second FOUP loader 282, and a single overhead loading track 260. The FOUP loaders 280 and 282 may perform both horizontal and vertical movements. In operation, the plate 122 of the first loader 280 is at POS1 and the plate 122 of the second loader 282 is at POS3. Again, FOUPs are shown in solid lines at these positions for purpose of illustration. The single overhead track 260 lowers a first FOUP F1 onto the plate 122 of the first FOUP loader 280 at POS1. The first FOUP loader 280 moves forward (in the direction of arrow 270 in FIG. 8), carrying the FOUP F1 from position POS1 to position POS2. The second FOUP loader 282 moves rearward from POS3 to an intermediate position POS1W aligned above POS1 and at the same vertical height as POS3. The first FOUP loader 280 then moves up, carrying the first FOUP F1 from POS2 to POS3, i.e., from the height of the load deck 108, to the level of the wafer access position 274. The second FOUP loader 282 moves down, to the position POS1 originally occupied by the first FOUP loader 280. The first FOUP loader 280 then moves the first FOUP F1 slightly forward, to dock the FOUP F1 at an opening 105 of the docking wall 106.

The wafers in the first FOUP F1 are then removed, processed and returned to FOUP F1, as described above, with the door remover 256 removing and replacing the door onto FOUP F1. The first FOUP loader 280 undocks the first FOUP F1. In the interim, the overhead loading track 260 has delivered a second FOUP F2 onto the second FOUP loader 282 at POS1. The first FOUP loader 280 moves FOUP F1 back down to POS2, while the second FOUP loader 282 moves the second FOUP F2 up from POS1 to POS1W.

The first FOUP loader 280 then moves rearward, carrying the first FOUP F1 from POS2 back to POS1 (to its original position). The second FOUP loader 282 moves the second FOUP F2 forward from POS2 to POS3, which is the wafer access position 274. The second FOUP loader 280 then docks the second FOUP F2. The door of FOUP F2 is removed and the wafers in FOUP F2 processed and returned, as described above relative to FOUP F1. FOUP F1, in the interim, is picked up by the overhead loading track 260 and moved to a subsequent processing or storage location within the fab facility. As described, FOUP F1 moves sequentially forward and then backward through positions POS1, POS2 and POS3. FOUP F2 moves sequentially forward and then back through positions POS1, POS1W and POS3. Of course, the sequence of FOUP movements may be reversed, with the first FOUP loader 280 moving up and then forward, and the second FOUP loader first moving down and then back. The FOUP movements described above and shown in FIG. 8 may be performed simultaneously to allow for simpler actuating mechanisms. However, simultaneous movement is not required.

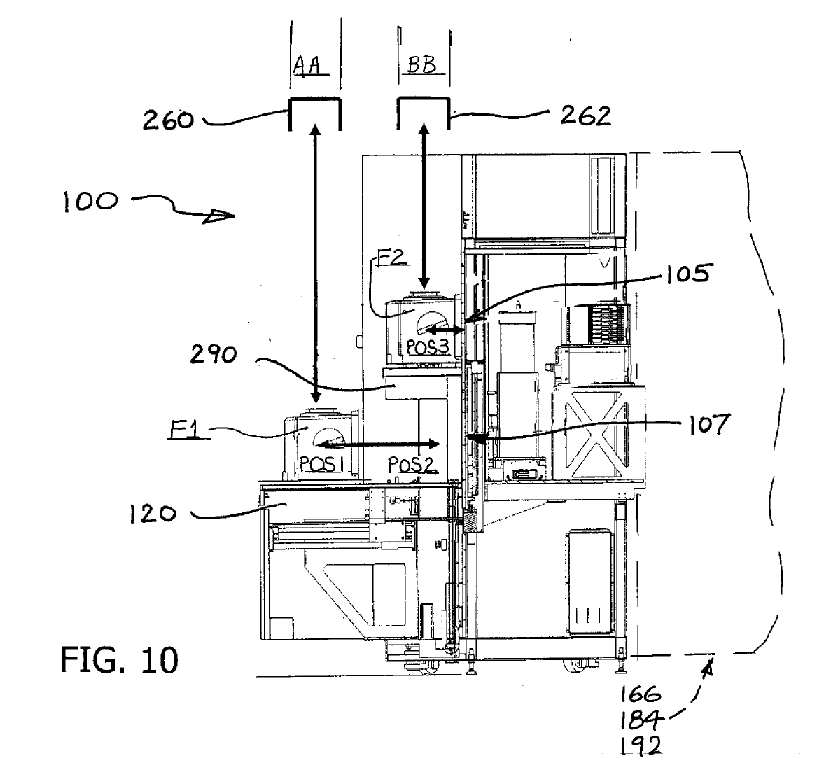

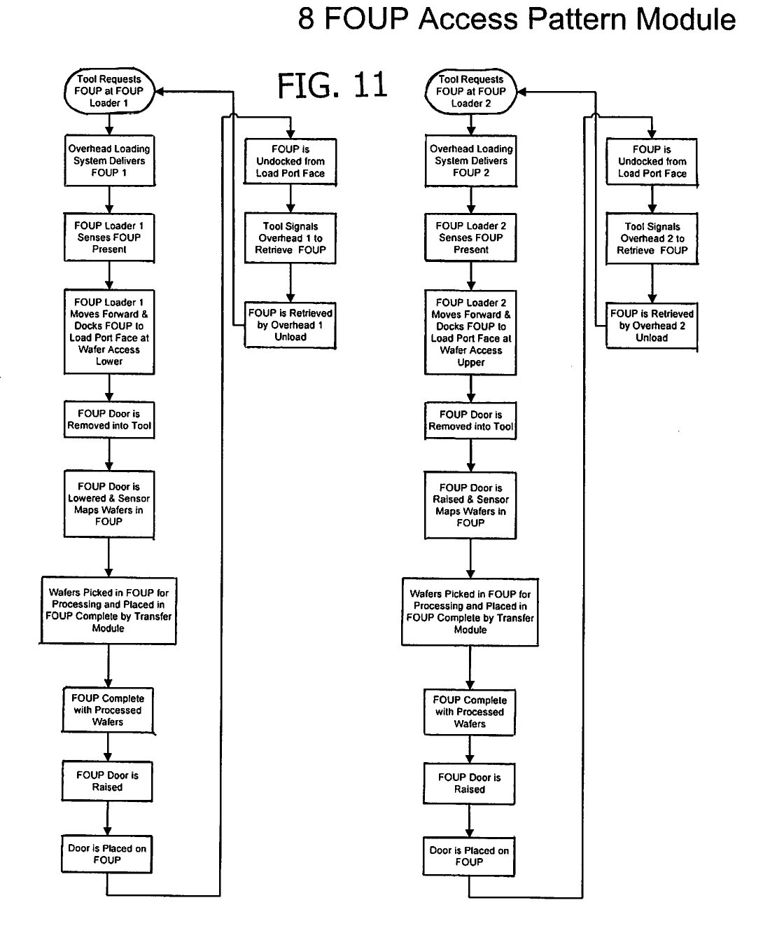

FIGS. 10 and 11 show an alternative design using two overhead loading tracks 260 and 262, and two actuator shuttles 120, but without the need for any vertical FOUP movement provided by a FOUP loader. Rather, in the design of FIGS. 10 and 11, all of the vertical FOUP movement is provided by the overhead loading tracks 260 and 262. In the loader shown in FIG. 10, eight docking openings are provided. Four lower docking openings 107 are provided at or near the level of the load deck 108, and four upper docking openings 105 are provided at the wafer access position 274. The lower docking openings 107 are shown in dotted lines in FIG. 1. After the overhead loading tracks 260 and 262 place a FOUP onto a FOUP plate 122 of a shuttle actuator 120, no vertical FOUP movement is needed to dock the FOUP.

Referring to FIGS. 10 and 11, the first overhead loading track 260 lowers a first FOUP F1 onto a FOUP plate 122 at POS1 of a first actuator shuttle 120. The actuator shuttle 120 then moves the FOUP F1 forward, from POS 1 to POS2, docking the FOUP F1 at a lower docking opening 107. The door of FOUP F1 is removed, the wafers held in FOUP F1 are removed, processed, returned to FOUP F1, and the door replaced. The first actuator shuttle 120 then undocks the FOUP and moves it rearward from POS2 back to its original POS1 position. The first overhead loading track 260 then removes the FOUP F1.

Referring still to FIGS. 10 and 11, the second overhead loading track 262 lowers a second FOUP F2 into POS3, onto a docking actuator 290, positioned vertically above the first shuttle actuator 120, at the level of an upper docking opening 105. The docking actuator 290 then docks the second FOUP F2 at an upper docking opening 105. The door of FOUP F2 is removed, the wafers in F2 unloaded, processed and replaced into FOUP F2, and then the door of F2 is replaced. The docking actuator 290 reverses direction, undocking the second FOUP F2. The second overhead loading track 262 then removes the second FOUP F2. The only movement required of the docking actuator 290 is the small forward movement used for docking the FOUP. This sequence of movements of FOUP F2 may be performed independently of the movement of FOUP F1, or the movements of F1 and F2 may be coordinated in various ways. However, the movements of F1 do not affect movements of F2, and vice versa, since each FOUP has its own actuator and docking window (in each of the four columns).

Referring to FIGS. 3 and 10, third and fourth FOUPs may be handled in the same way. Since this design has 8 docking openings, and since a FOUP may be docked any docking opening independent of the position of any other FOUP on the loading system, all 8 FOUPS may be docked at the same time. Accordingly, if desired, the transfer robot(s) in the system of FIG. 10 can access any one of 8 docked FOUPs.

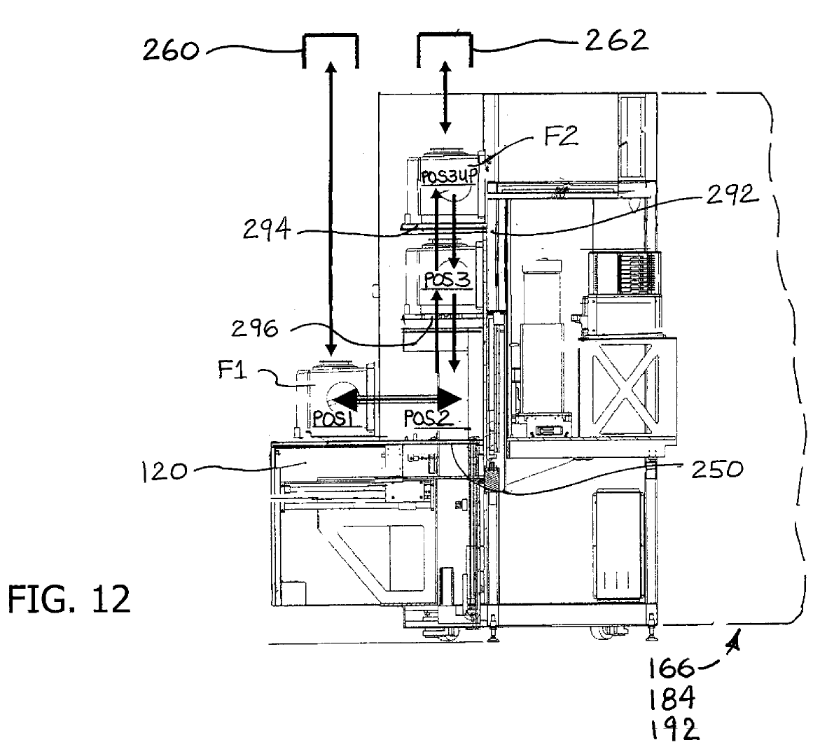

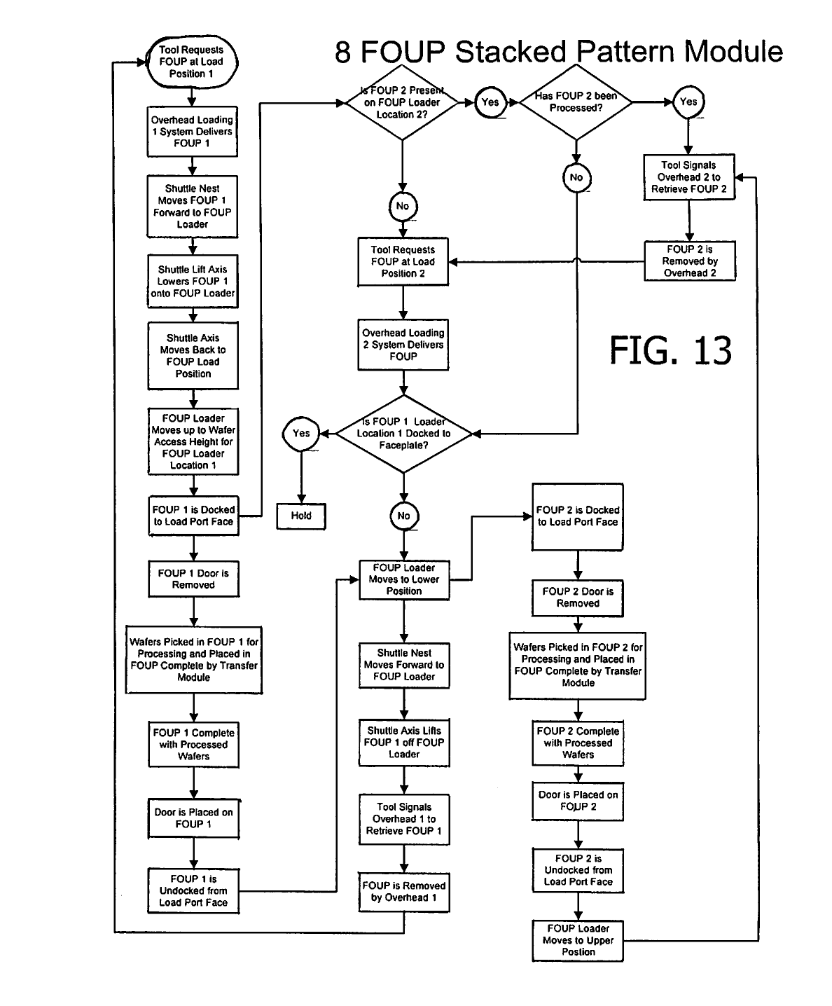

FIGS. 12 and 13 show another alternative method of operation of a loading system 100. This operation uses first and second overhead loading tracks 260 and 262, a single shuttle actuator 120, and a single two level or stacked FOUP loader 292. The FOUP loader 292, however, has an upper FOUP plate 294 stacked vertically above a lower FOUP plate 296, with a docking actuator associated with each of the plates 292 and 294. Referring to FIGS. 12 and 13, the first or outer load track 260 lowers a first FOUP F1 into POS1 on the FOUP plate 122 of a shuttle actuator 120, at the load deck 108. The first FOUP F1 is then moved onto the lower FOUP plate 296 of the FOUP loader 292 from POS1 to POS2, then lifted up to POS3, docked, and opened, in the same way as in FIG. 6, as described above. The wafers then move sequentially to a buffer, a processor, back to a buffer, and then back into a FOUP, via transfer and process robots.

While the first FOUP F1 is at the POS 3 wafer access position 274, or docked at a docking opening 105, the second overhead loading track 262 delivers a second FOUP F2 onto the upper plate 294 of the FOUP loader 292. This position, referred to here as the stack position, is labeled as POS3UP in FIG. 12. The stack position POS3UP is above the wafer access position 274, as shown in FIG. 12, and may be aligned above POS3, which typically is aligned above POS2. The FOUP loader 292 is now holding both the first FOUP F1 at POS3 and the second FOUP F2 at POS3UP. The FOUP loader then moves down, bringing the first FOUP F1 back down to POS2, substantially at the load deck level, and simultaneously lowers the second FOUP F2 down from POS3UP to the POS3 wafer access position 274. The second FOUP F2 is then docked and opened, with wafers in the second FOUP F2 handled, processed and returned, in the same way as with FOUP F1 described above. The shuttle actuator 120 in the interim has removed FOUP F1 from the lower plate 296 of the loader 292 and returned FOUP F1 from POS2 back to its original position at POS1. The first overhead track 260 then removes FOUP F1 and carries it to a subsequent processing or storage location within the fab. After processed wafers are returned to FOUP F2, and the door reinstalled, FOUP F2 is undocked, and lifted off of the processing system via the second overhead track 262.

In each of the designs described above, processed wafers may be returned to their original FOUP, or they may be returned to a different FOUP, depending on the processing carried out, and other factors. In some fabs, the unprocessed wafers may be delivered to the loading system in a so-called “dirty” FOUP. After processing, the “clean” wafers are then returned to a different “clean” FOUP (referred to below as an auxiliary FOUP), typically docked at a docking opening 105 different from the docking opening at which the “dirty” FOUP was docked. The loading system 100 as described above may operate in this way, with the transfer robot(s) controlled to pick unprocessed wafers from one FOUP and return them after processing to a different FOUP. Similarly, the process robot(s) and/or the transfer robot(s) may handle both unprocessed and processed wafers using the same end effector, or using a different end effector. In particular, in some designs, unprocessed wafers may be handled only by dedicated unprocessed wafer end effectors, while processed wafers are handled only by dedicated processed wafer end effectors, to reduce potential for cross contamination.

As is apparent from the description above, the methods described may be performed using many different types of apparatus, as the methods are directed to the movements and sequences of events, and not to apparatus providing such movements and sequences of events. The specific elements described relative to FIGS. 6-13 are mere examples of apparatus. The types and numbers of transfer and process robots may also be changed as may be desired. While the drawings show 8 FOUP loading systems, the inventive concepts described here may also be used with loading systems having 2, 3, 4, 5, 6, 7, 8, 9, 10, 11, 12 or more FOUP positions.

The number and type of buffers used may also be varied. In addition, in certain applications, buffers and transfer robots may be entirely omitted, with one or more process robots performing all wafer handling and movement. In some applications, the buffers may optionally be moved laterally, via lateral buffer actuators, along with, or in place of, vertically moving indexing buffers, or fixed buffers. The rows and columns described above generally relate to multiple aligned positions. However, it is readily apparent that one or more positions nominally in a row or column may be off set, or moved out of alignment, without affecting operation of the loading system. Accordingly, rows and columns, as used here, includes arrangements having one or more misaligned, joggled, or staggered positions.

The term work piece or wafer here means any flat article, including semiconductor wafers and other substrates, such as glass, mask, and optical or memory media, MEMS substrates or any other work piece having, or on which, micro-electronic, micro-mechanical, micro-electro-mechanical, or micro-optical devices, may be formed. The term “between” includes movement and/or placement at the ending points, e.g. a FOUP, a buffer or a processor. Although operations using FOUPs have been described, other types of containers or carriers may alternatively be used. Terms such as “forward”, “rearward”, “upper”, “lower”, and the like when used here refer to the positions of the respective elements shown in the drawing figures, although the invention is not necessarily limited to such positions or relationships. Indeed, the specific directions of movement described in the claims may of course be reversed, to perform clearly equivalent steps or methods. Similarly, terms such as “vertical”, “inwardly”, “outwardly”, “towards”, “away from”, and similar terms, as used here mean “in the general direction of”, and not limited to their geometric definitions. The terms “up” and “down” refer to the direction of gravity. The terms “above” and “below” indicate different vertical positions, and with the same or different horizontal positions. The term “aligned above” mean different vertical positions and the same horizontal position.

Thus, novel methods and apparatus have been shown and described. Various changes and substitutions of equivalents may of course be made, without departing from the spirit and scope of the invention. The invention, therefore, should not be limited, except to the following claims, and their equivalents.

1. A method for moving wafers into and out of a processing system, comprising:
lowering a first wafer carrier into a first position on a wafer loading system;
moving the first wafer carrier substantially in a first direction, from the first position to a second position;
lifting the first wafer carrier to a third position;
moving wafers from the first wafer carrier out of the wafer loading system and into a processing system;
moving the wafers back into the wafer loading system and returning the wafers to the first wafer carrier or to an auxiliary wafer carrier;
lowering a second wafer carrier into the first position of the wafer loading system; and
lifting the first wafer carrier from the wafer loading system.

2-8. (canceled)

9. The method of claim 1 wherein the first wafer carrier is lowered to and lifted from the first position via first and second overhead carrier loading elements, respectively.

10. The method of claim 9 further comprising:
lowering a third wafer carrier from the first overhead carrier loading element into a fourth position of the wafer loading system;
moving the third wafer carrier substantially horizontally from the fourth position to a fifth position;
lifting the third wafer carrier to a sixth position;
docking the third wafer carrier at a docking position;
removing a door from the third wafer carrier;
moving wafers from the third wafer carrier out of the loading system and into a processing system;
moving the wafers taken from the third wafer carrier back into the loading system and returning them to the third wafer carrier;
replacing the door onto the third wafer carrier;
undocking the third wafer carrier;
lowering a fourth wafer carrier from the first overhead carrier loading element into the fourth position of the wafer loading system; and
lifting the third wafer carrier from the wafer loading system via a second overhead carrier loading element.

11. (canceled)

12. A method for moving wafers, comprising:
lowering a first wafer carrier into a first position of a wafer loading system;
moving the first wafer carrier substantially in a first direction, from the first position to a second position;
lifting the first wafer carrier to a third position;
lowering a second wafer carrier into the first position of the wafer loading system;
moving a first lot of wafers from the first wafer carrier into a wafer processing system;
moving the first lot of wafers back into the first wafer carrier or into an auxiliary wafer carrier;
moving the second wafer carrier up to an intermediate position vertically above the first position;
moving the first wafer carrier down from the third position back to the second position;
moving the second wafer carrier substantially in the first direction from the intermediate position into third position;
moving the first wafer carrier from the second position back to the first position; and
lifting first wafer carrier up and removing it from the wafer loading system.

13. The method of claim 12 wherein the second wafer carrier is loaded into the wafer loading system at the intermediate position vertically above the first position.

14-19. (canceled)

20. The method of claim 12 wherein the first and second wafer carriers are lowered to and lifted from the first position via an overhead carrier loading element aligned over the first position.

21. The method of claim 20 further comprising:
lowering a third wafer carrier from the overhead carrier loading element into a fourth position of the wafer loading system;
moving the third wafer carrier substantially horizontally from the fourth position to a fifth position;
lifting the third wafer carrier to a sixth position;
moving a third lot of wafers from the third wafer carrier out of the loading system and into a processing system;
moving the third lot of wafers back into the loading system and returning the third lot of wafers to the third wafer carrier;
lowering a fourth wafer carrier from the overhead carrier loading element into the fourth position of the wafer loading system;
lowering the third wafer carrier down from the sixth position back to the fifth position;
lifting the fourth wafer carrier up from the fourth position to an intermediate position above the fourth position;
moving the third wafer carrier substantially horizontally from the fifth position back to the fourth position; and
lifting the third wafer carrier from the wafer loading system via the overhead carrier loading element.

22. The method of claim 20 wherein the first position and the fourth position are adjacent to each other within a first row of positions.

23. A method comprising:
lowering a first wafer carrier into a first position of a wafer loading system;
moving the first wafer carrier substantially in a first direction from the first position to a second position;
moving a first lot of wafers from the first wafer carrier into a wafer processing system;
returning the first lot of wafers back into the first wafer carrier or into an auxiliary wafer carrier;
moving the first wafer carrier from the second position to the first position;
lowering a second wafer carrier into third position of the wafer loading system, with the third position vertically above the second position;
moving a second lot of wafers from the second wafer carrier into the wafer processing system;
returning the second lot of wafers back into the second wafer carrier;
lifting the first wafer carrier up off of the loading system; and
lifting the second wafer carrier up off of the loading system.

24. The method of claim 23 wherein the processing system includes two or more docking positions, further comprising simultaneously maintaining a wafer carrier at each of the docking positions.

25. The method of claim 23 wherein the second wafer carrier is lowered into the first position while first carrier is in the first position or the second position or between the first and second positions.

26-27. (canceled)

28. The method of claim 1 wherein the first and second wafer carriers are lowered to and lifted from the first and third positions via first and second overhead carrier loading elements, respectively.

29. The method of claim 28 further comprising:
lowering a third wafer carrier from the first overhead carrier loading element into a fourth position of the wafer loading system;
moving the third wafer carrier substantially horizontally from the fourth position to a fifth position;
moving wafers from the third wafer carrier out of the loading system and into a processing system;
moving the wafers taken from the third wafer carrier back into the loading system and returning them to the third wafer carrier; and
lowering a fourth wafer carrier from the second overhead carrier loading element into sixth position substantially aligned over the fifth position.

30. A method comprising:
lowering a first wafer carrier into a first position of a wafer loading system;
moving the first wafer carrier substantially in a first direction, from the first position to a second position;
lifting the first wafer carrier to a third position;
moving a first lot of wafers out of the first wafer carrier and into a wafer processing system;
returning the first lot of wafer to the first wafer carrier or into an auxiliary wafer carrier;
lowering a second wafer carrier into a stack position substantially aligned above the third position;
lowering the first wafer carrier from the third position back to the second position;
lowering the second wafer carrier from the stack position to the third position;
moving the first wafer carrier from the second position back to the first position;
moving a second lot of wafers out of the second wafer carrier and into a wafer processing system;
returning the second lot of wafers to the second wafer carrier; and
lifting the first wafer carrier off of the wafer loading system.

31. The method of claim 30 wherein the second position and the stack position are on a vertically movable wafer loader.

32-34. (canceled)

35. The method of claim 34 further comprising:
lowering a third wafer carrier from the first overhead carrier loading element into a fourth position of the wafer loading system;
moving the third wafer carrier substantially horizontally from the fourth position to a fifth position;
lifting the third wafer carrier to a sixth position;
docking the third wafer carrier at a docking position;
removing a door from the third wafer carrier;
moving wafers from the third wafer carrier out of the loading system and into a processing system;
moving the wafers taken from the third wafer carrier back into the loading system and returning them to the third wafer carrier;
replacing the door onto the third wafer carrier;
undocking the third wafer carrier;
lowering a fourth wafer carrier from the second overhead carrier loading element into the stack position; and
lifting the third wafer carrier from the wafer loading system via the first overhead carrier loading element.

36. A wafer loading system comprising:
a docking wall having a plurality of docking openings;
a carrier loading system on a first side of the docking wall, with the carrier loading system having:
first and second rows of carrier loading positions accessible by a first overhead loading element, and a second row of carrier loading positions accessible by a second overhead loading element;
a shuttle actuator positioned to move a carrier to or from a position in the first row to or from a position in the second row;
a carrier loader positioned to receive a carrier from the shuttle actuator, at the second row; and
a lift actuator linked to the carrier loader for lifting and lowering the carrier load.

37. The system of claim 36 wherein each of the rows has two or more carrier columns, and further comprising a shuttle actuator, a carrier loader, a lift actuator, and a docking opening associated with each of the carrier columns.

38. (canceled)

39. A wafer loading system comprising:
a docking wall having a plurality of docking openings;
a carrier loading system on a first side of the docking wall, with the carrier loading system having:
a first row of carrier loading positions accessible by an overhead wafer carrier loading and unloading element, and a second row of carrier loading positions adjacent to the first row;
a first carrier loader having a first carrier plate, a first shuttle actuator for horizontal movement and a first lift actuator for vertical movement;
a second carrier loader having a second carrier plate, a second shuttle actuator for horizontal movement and a second lift actuator for vertical movement;
with the first and second carrier loaders adapted to the move the first and second carrier plates in substantially equal and opposite directions, respectively.

40. The system of claim 39 wherein each of the rows has two or more carrier columns, and further comprising first and second carrier loaders and a docking opening associated with each of the carrier columns.

41. (canceled)

42. A wafer loading system comprising:
a docking wall having a first row of docking openings and a second row of docking openings above the first row;
a carrier loading system on a first side of the docking wall, with the carrier loading system having:
a first row of carrier loading positions accessible by a first overhead loading element, and a second row of carrier loading positions accessible by a second overhead loading element;
a shuttle actuator positioned to move a first carrier from a position in the first row to a position at a docking opening in the first row of docking openings; and
a docking actuator positioned to dock a second carrier at a docking opening in the second row of docking openings.

43. The system of claim 42 further comprising:
at least one robot and at least one buffer on a second side of the docking wall, opposite from the first side, with the robot adapted to move wafers between a wafer carrier and the buffer.

44. The system of claim 42 wherein the first and second rows of docking openings each includes two or more docking openings, further comprising a shuttle actuator associated with each of the docking openings in the first row of docking openings, and further comprising a docking actuator associated with each of the docking openings in the second row of docking openings.

45. A wafer loading system comprising:
a docking wall having a plurality of docking openings;
a carrier loading system on a first side of the docking wall, with the carrier loading system having:
a carrier loading position accessible by a first overhead loading element;
a carrier loader having upper and lower carrier holding plates, with the upper carrier plate accessible by a second overhead loading element;
an upper docking actuator attached to the upper carrier plate and a lower docking actuator attached to the lower carrier plate;
a lift actuator connected to the carrier loader for lifting and lowering the carrier loader; and
a shuttle actuator adapted to move a carrier from the first carrier loading position onto the lower carrier holding plate.

46. The system of claim 45 further comprising at least one robot and at least one buffer on a second side of the docking wall, opposite from the first side, with the robot adapted to move wafers between a wafer carrier and the buffer.

47. The system of claim 1 with the carrier loading system having a plurality of wafer carrier columns, with each column having a carrier loading position and a carrier loader, and with the carrier loading positions of the columns forming a first row of carrier loading positions aligned under the first overhead carrier loading element, and with the upper carrier plates of the carrier loaders forming a second row of carrier loading positions aligned under the second overhead loading element.
